(19) United States
(12) Patent Application Publication
(10) Pub. No.: US 2007/0252216 A1
(43) Pub. Date: Nov. 1, 2007

(54) Semiconductor device and a method of manufacturing such a semiconductor device

(75) Inventor: Nawaz Muhammad, Munchen (DE)

Correspondence Address: MORRISON & FOERSTER LLP, 1650 TYSONS BOULEVARD, SUITE 400, MCLEAN, VA, 22102, US

(73) Assignee: INFINEON TECHNOLOGIES AG, Munchen (DE)

(21) Appl. No.: 11/413,125

(22) Filed: Apr. 28, 2006

(51) Int. Cl. H01L 29/78; H01L 21/8238

(52) U.S. Cl. 257/369; 438/233; 438/199; 438/478; 257/615; 257/616

(57) ABSTRACT

A semiconductor device, specifically a Complementary Metal Oxide Semiconductor (CMOS) device, has a substrate on which are formed first and second field effect transistors. Each of the field effect transistors comprises a source-drain region, a channel of either an n-type or a p-type conductivity semiconductor material formed on the substrate, a first gate region, and a first dielectric region that separates the first channel from the first gate region. However, dissimilar semiconductor materials are used to form the channel regions of the first and second field effect transistors so that high electron and hole mobility can be achieved.

### TECHNICAL FIELD OF THE INVENTION

The invention relates to a semiconductor device and method of manufacturing a semiconductor device.

### BACKGROUND OF THE INVENTION

Mainstream semiconductor device production currently tends to center on conventional silicon and silicon-on-insulator (SOI) based Metal Oxide Semiconductor (MOS) and CMOS technologies. The main thrust of research is based around reduction in device feature size to nanometer scale that thereby provides improvements in the device performance. As the performance of a CMOS chip is generally measured by its integration density, switching speed and power dissipation, the transistor channel length and parasitic resistive-capacitive (RC) constant are the two major contributors that finally limit the circuit speed. The transistor switching delay (i.e. propagation delay) of a typical CMOS device, is a function of the device load capacitance, the drain voltage, and the saturation currents for both the n- and p-channel devices, limit the maximum operating frequency for an integrated circuit device.

Improvement of performance in conventional silicon MOS and CMOS technologies through reduction of feature size, is becoming extremely difficult, if not impossible. Additionally, the electrical properties (i.e., material transport properties such as carrier mobility) of silicon itself provide another source of performance limitation in terms of propagation delay. It should be noted here that conventional bulk silicon and SOI based CMOS transistors, which comprise n- and p-channel MOS transistors on the same substrate (i.e. silicon) suffer from imbalance owing to different electron and hole mobility values. This imbalance is caused by higher electron mobility than hole mobility in the channel region (μn,=1350 cm2/V-s; μh=450 cm2/V-s). Hence, the n-MOS transistor operates faster than the p-MOS transistor. Also, this imbalance of electron and hole-mobility in CMOS devices is further exacerbated in devices with strained silicon channels, since the strained silicon channel (i.e. process induced strain in Si and Si channel on relaxed SiGe type) does not enhance the hole mobility in p-MOS transistors as much as it does the electron mobility in n-MOS transistors.

Another common problem associated with all SOI type CMOS devices is the self heating effect. Self-heating is caused by the conversion of electrical energy into thermal energy and it increases the lattice temperature which in turn influences the electron mobility, ionization and saturation velocity. The greater the heat generated in the active region of the device, the greater will be the influence on device performance. Devices operating at high drain voltage and current suffer from the reduction of carrier mobility and saturation velocity, resulting in reduction in the drain current and transconductance. Other severe problems such as increased electromigration and enhanced impact ionization because of increased device heating, affect the reliability of the devices. This problem is basically associated with difference in the thermal conductivities of silicon (Si), silicon-germanium alloys (SiGe) and silicon dioxide (Sio2) for all the SOI type devices discussed earlier. For example, the thermal conductivity of bulk silicon is 1.5, compared to Si0.75Ge0.25 of 0.085, Ge of 0.6 and SiO2 of 0.014 W/cm-° C. The SiO2 has a poor thermal conductivity value compared with the Si and the Si0.75Ge0.25 (an alloy composition of 0.75 silicon and 0.25 germanium is typical for silicon-germanium alloys used in Si/SiGe device design). The issue of self-heating is therefore extremely important for a number of electronic device applications where the ability to remove the power which is dissipated as heat is paramount.

### BRIEF SUMMARY OF THE INVENTION

The invention provides a CMOS device which has an improved performance over conventional devices. In preferred embodiments, the invention provides a CMOS device in which thermal problems, namely self-heating, are reduced as compared with conventional devices. The invention also provides a CMOS device that has an improved reliability as compared to conventional devices and one which can be produced with a low fabrication time and cost.

In a first aspect of the invention, a semiconductor device includes a substrate on which are formed a first field effect transistor comprising a first source-drain region, a first channel of a first, n-type conductivity semiconductor material formed on the substrate, a first gate region, and a first dielectric region that separates the first channel from the first gate region; and a second field effect transistor including a second source-drain region, a second channel of a second, p-type conductivity semiconductor material dissimilar to the first material and formed on said substrate, a second gate region, and a second dielectric region that separates the first channel from said first gate region.

It will be appreciated that in the invention dissimilar semiconductor materials are used to form the channel regions of the first and second field effect transistors so that high electron and hole mobility can be achieved.

Preferably, the substrate on which the first and second channels of the respective firsthand second field effect transistor are formed comprises a silicon substrate.

Preferably also, the first, n-type conductivity semiconductor material used for the first channel also comprises silicon and the second p-type conductivity semiconductor material used for the second channel comprises a SiGe alloy. This keeps the benefits of the existing electron mobility of Si material and the higher hole mobility of Ge/SiGe material in order that a more balanced CMOS chip can be designed with improved speed performance.

Advantageously, however, on a silicon substrate the first, n-type conductivity semiconductor material used for the first channel comprises a different material to that of the substrate. In a preferred embodiment, gallium arsenide (GaAs) is used as the first, n-type conductivity semiconductor material for the first channel and silicon-germanium (SiGe) is used as the second p-type conductivity semiconductor material for the second channel. This enables an even faster chip to be designed with further enhanced speed performance. Compared to conventional Si (silicon: μn=1350 cm2/V-s) technology, a GaAs (Gallium Arsenide: μn=8500 cm2/V-s) material system exhibits superior transport properties, namely a five times higher electron mobility and higher low field electron velocity. Similarly, the electron and hole mobility values of Ge (μn=3900 cm2/V-s, μh=1900 cm2/V-s) and Si0.75Ge0.25 (μn=2100 cm2/V-s, μh=812 cm2/V-s) are superior to that of Si.

In order to minimize thermal problems (i.e., self-heating). Preferably, the substrate comprises a layer of gallium phosphide (GaP), which is a compound semiconductor, over a base silicon layer. A GaP layer will provide insulation and will grow directly on a Si substrate since it has a small lattice mismatch with Si (<0.4%). The lattice constants of GaP and Si respectively are 5.4505 and 5.431 Å at 300 K. The thermal conductivity of GaP, namely 1.1 W/cm-° C., is fairly close to that of Si, which allows efficient heat extraction so that a high output power can be achieved. In addition, GaP is highly suitable for high temperature electronic applications in, for example, jet aircraft engine control systems, satellite system electronics and the like, because of its wide bandgap of 2.26 eV, its low intrinsic carrier concentration of 2 cm-3, its high dielectric constant of 11.1, its high breakdown field of 1×106 V/cm, and its good thermal stability. Unlike wafer bonding and SIMOX process typical in SOI type devices, growth of heteroepitaxy GaP on a Si substrate allows sharp interface quality under ultra high vacuum in a single epitaxy step, thus minimizing the fabrication time and cost. As a result of the sharp interface and controlled Si growth on GaP, the invention enables an ultra thin body SOI to be produced. GaP crystal on a silicon substrate has been grown by several different techniques such as solid source molecular beam epitaxy (see Xiaojun et al., J. Vac. Sci. Technol. B 22 (3), pp. 1450-1454, May 2004) and plasma enhanced chemical vapour deposition (S. W. Choi et al., J. Vac. Sci. Technol. A 11 (3), pp. 626-630, May 1993, and Japanese patent no JP1018999 entitled “Growth of GaP crystal on Si substrate”).

There is, however, a heteroepitaxy growth problem associated with the direct growth of a GaAs layer to form the first, n-type conductivity semiconductor material for the first channel on a Si or GaP substrate as there is a large lattice mismatch. The lattice constant of GaAs is 4.6532 Å as compared to that for silicon of 5.431 Å. Preferably, therefore, at least one but advantageously a plurality of intermediate layers each in the form of a superlattice stack is provided between the Si basal substrate layer and the GaAs layer forming the first channel to absorb the lattice mismatching between GaAs and Si. The growth of GaAs on a GaP/Si substrate can therefore be achieved.

Preferably, each intermediate layer is composed of two thin alternating layers that may each be between 5 nm and 10 nm thick in a superlattice stack of between four and six layers. A first intermediate layer laid down over the GaP layer above a Si basal layer preferably comprises alternating layers of GaP and gallium arsenide-phosphide (GaAsP). A second intermediate layer laid down over the first intermediate layer preferably comprises alternating layers of GaAsP and GaAs. Such an arrangement is described, for example, in U.S. Pat. No. 4,789,421.

Alternatively, the intermediate layer may comprise a superlattice structure comprising a Ge layer on a Si substrate.

In a second aspect of the invention, a method is provided of manufacturing a semiconductor device comprising a substrate on which are formed first and second field effect transistors wherein said first field effect transistor including a first channel of a first, n-type conductivity semiconductor material formed on the substrate and the second field effect transistor comprises a second channel of a second, p-type conductivity semiconductor material dissimilar to the first the material and formed on the substrate. The method comprises the steps of depositing a first layer of a first-type semiconductor material on the substrate to form said first channel;

removing the first layer at a region where a second-type field effect transistor is to be formed; depositing a second layer of a second-type semiconductor material dissimilar to the first material on said substrate in said region where the first material was removed; forming an isolation region between said first and the second materials; depositing first and second gate dielectric layers over the first and second materials respectively; depositing gate electrode layers over the first and said second gate dielectric layers; and forming source-drain contact layers at each of the two gate regions over the first and the second materials.

In embodiments wherein the first-type semiconductor material comprises silicon, preferably the deposition of the GaP layer and the first layer of the first-type semiconductor material is accomplished by epitaxial growth in a single epitaxy growth step, for example by using molecular beam epitaxy, vapor phase epitaxy or a metalorganic chemical vapour deposition (MOCVD) technique.

In another embodiment, the method comprises the additional step of depositing on a Si substrate a GaP layer and at least one superlattice stack intermediate layer. Preferably the deposition of said GaP layer, the at least one superlattice stack intermediate layer and the first layer of the first-type semiconductor material is also accomplished by epitaxial growth in a single epitaxy growth step, for example by using a Molecular Beam Epitaxy (MBE) growth process.

### BRIEF DESCRIPTION OF THE DRAWING

The invention is described below in more detail with reference to the exemplary embodiments and drawings, in which:

FIGS. 1 and 2 are sectional views through first and second embodiments of semiconductor devices in accordance with the invention.

FIGS. 3 and 4 are flow diagrams illustrating preferred methods of manufacturing the semiconductor devices shown in FIGS. 1 and 2, respectively.

### DETAILED DESCRIPTION OF THE INVENTION

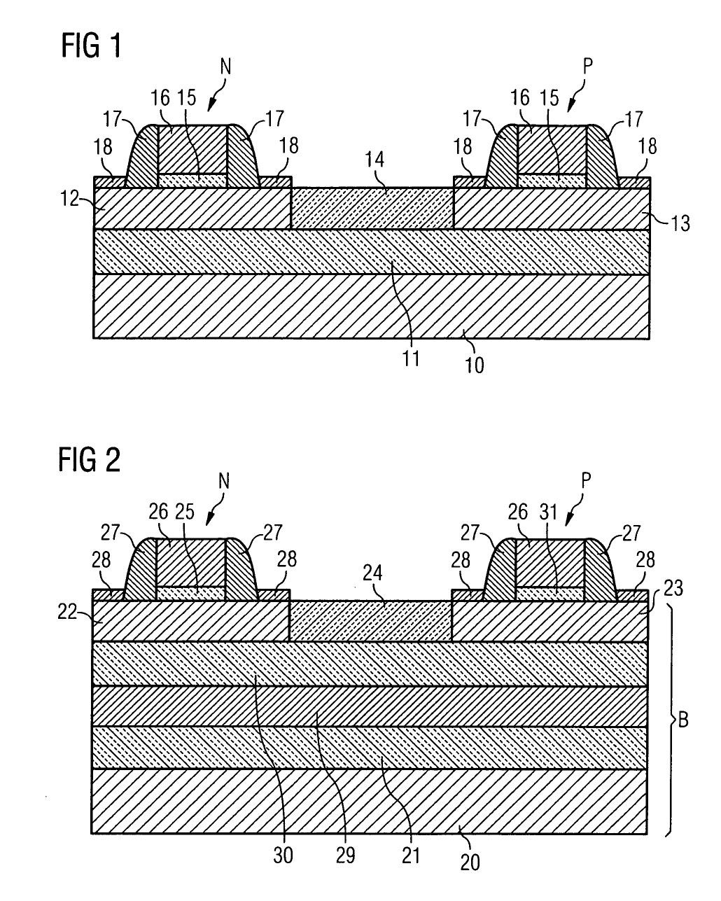

In both of the semiconductor devices shown in FIGS. 1 and 2, multiple semiconductor materials are integrated to form the device on a Si substrate 10 and 20 respectively. It should be noted that both FIG. 1 and FIG. 2 are diagrammatic and are not drawn to scale, the dimensions of the thicknesses of the various layers of semiconductor materials being exaggerated for greater clarity. Corresponding parts in both figures are given the same hatching and generally have the same references numerals but separated by ten, for example the Si substrate in FIG. 1 has the reference numeral 10 whereas in FIG. 2 the Si substrate has the reference numeral 20.

In both FIG. 1 and FIG. 2, the semiconductor device comprises a CMOS device wherein both an n-MOSFET device N and a p=MOSFET device P are formed on the same Si substrate 10, 20.

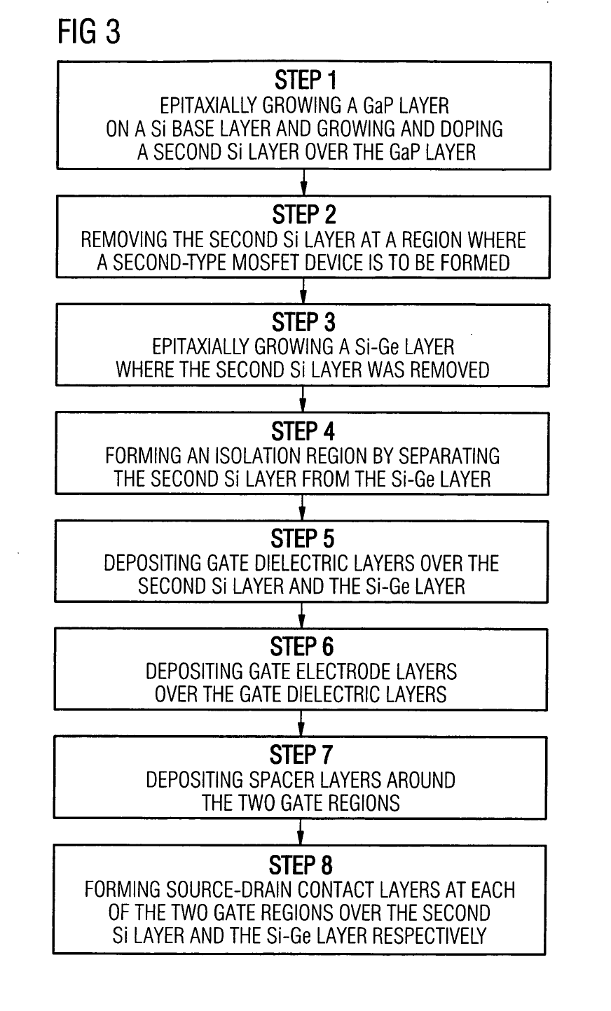

In the first embodiment shown in FIG. 1, the substrate also comprises a layer 11 of GaP provided over a base Si layer 10 to provide insulation and to reduce thermal problems caused by self-heating and the N and P devices are formed on the layer 11. Each of the N and P devices comprises a channel of appropriate type conductivity semiconductor material 12, 13 respectively formed on the layer 11 and separated by an isolation region 14. In FIG. 1, the first, n-type conductivity semiconductor material used for the channel 12 of the N device also comprises silicon and the second p-type conductivity semiconductor material used for the channel 13 of the P device comprises a silicon-germanium alloy. The manner in which this CMOS device is manufactured will now be described with reference to FIG. 3.

After provision of the Si substrate 10, the GaP layer 11 is first grown on the Si layer 10. Over this, a second thin Si layer 12 is then grown to form part of the first channel material for the n-MOSFET device N. The second thin Si layer 12 can be p-type doped in-situ during an epitaxy growth step. The thickness of this second Si layer 12 may be between 10 nm and 20 nm. Since a high crystalline quality undoped GaP layer, 11 and the second Si layer 12 can be directly grown in a single growth step on a Si substrate 10 using either molecular beam epitaxy or vapor phase epitaxy or a metalorganic chemical vapour deposition (MOCVD) technique, a reduction in the fabrication time and cost of a wafer as compared to the conventional but tedious SIMOX or wafer bonding processes used in SOI type devices can be achieved. The thickness of the GaP layer 11 may be between 50 nm and 150 nm. Essentially, therefore, a complete base structure comprising the layers 10, 11, and 12 with an excellent interface quality in the Si/GaP interface can be epitaxially grown initially in a single epitaxy growth step (STEP 1). The second Si layer 12 is then dry etched at a place where the p-MOSFET device P is to be defined (STEP 2).

In order to form the p-MOSFET device P, a Si0.75Ge0.25 layer 13 is then epitaxially grown, which may be between 10 nm and 30 nm thick and n-type doped in-situ during epitaxy growth step (STEP 3). The composition of Ge in this layer may be tuned (x=0.2−0.3) to match the lattice constant exactly with that of the GaP layer 11 beneath it. An isolation region 14 is then defined first by anisotropically etching the Si layer 12 and the Si0.75Ge0.25 layer 13 to separate these layers and then by depositing silicon nitride (Si3N4) or SiO2 by a conventional CVD technique (STEP 4).

Gate oxide layers 15 are then formed over the layers 12 and 13 (STEP 5). These layers 15 may be thermally grown and may typically comprise SiO2 or another high-K material such as tantalum oxide (TaO5), hafnium oxide (Hf02) or other suitable gate dielectric material. Gate electrode layers 16 are then deposited (STEP 6) and may be of polysilicon or any other suitable metal with the desired work function. The p and n doping in the channel layers 12 and 13 and the gate work function, i.e. the gate material, will define the threshold voltage of the device.

Once the gate electrode layers 16 have been deposited, the source-drain regions can be formed (STEPS 7 and 8). Preferably, nitride spacer layers 17 are first deposited around the gate region formed by the gate oxide layers 15 and the gate electrode layers 16 (STEP 7). These nitride spacers may be between 25 nm and 100 nm thick. After this a source-drain implant step is performed. These implants may comprise arsenic (As) for the n-MOSFET device N and boron (B) for the p-MOSFET device P. Finally, the source-drain contact layers 18 of any suitable metal are deposited (STEP 8).

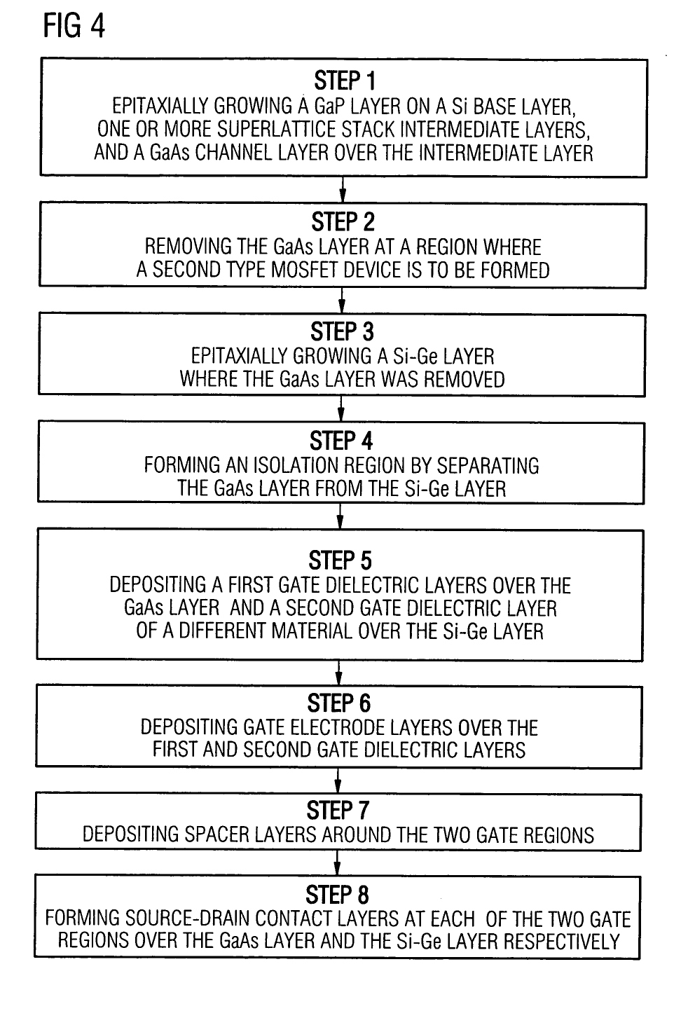

Turning now to the embodiment shown in FIG. 2, again a GaP layer 21 is first grown on a Si substrate 20. However, in this embodiment, the channel layer 22 of the n-MOSFET N is composed of GaAs material and the channel layer 23 of the p-MOSFET P is composed of a Si0.75Ge0.25 material. As discussed above, one problem associated with the growth of GaAs on a GaP/Si substrate 21, 20 is lattice mismatch between the Si and GaAs layers. This problem is overcome in the present embodiment by using intermediate layers 29 and 30, each of which comprises a superlattice stack of between four and six layers. The manner in which this CMOS device is manufactured will now be described with reference to FIG. 4.

The first layer 29 is laid down over the GaP layer 21 and comprises alternating layers of GaP and GaAsP each being between 5 nm and 10 nm thick and left undoped. The second layer 30 is laid down over the layer 29 and comprises alternating layers of GaAsP and GaAs, again each being between 5 nm and 10 nm thick and left undoped. Each layer 29, 30 may be grown between four and six times to absorb the lattice mismatching. Initially, a base structure B comprising the Si layer 20, the GaP layer 21, the intermediate layers 29 and 30, and the first channel layer 22 of the n-MOSFET N is first grown in a single epitaxy step (STEP 1) using either a molecular beam epitaxy (MBE) or a metalorganic chemical vapor deposition (MOCVD) technique. The top GaAs channel layer 22 may be intrinsically p-type doped to a desired value to form a p-well for the n-MOSFET N. The thickness of GaAs channel layer is preferably between 10 nm and 20 nm thick and the thickness of the Gap layer 21 is preferably between 50 nm and 150 nm. Once the base structure B has been formed, a portion of the top GaAs layer 22 is dry etched at a place where the p-MOSFET P is to be formed (STEP 2). A Si0.75Ge0.25 layer 23 is then epitaxially grown (STEP 3). This layer 23 is preferably between 10 nm and 30 nm thick and n-type doped in-situ during the epitaxy growth step. As in the first embodiment, the composition of the Ge may be tuned (x=0.2−0.3) to match the lattice constant exactly with the GaP layer 21 underneath. An isolation region 24 is then defined first by anisotropically etching the GaAs layer 22 and the Si0.75Ge0.25 layer 23 to separate these layers and then by depositing silicon nitride or silicon dioxide by a conventional CVD technique (STEP 4).

The gate dielectric materials are then grown (STEP 5). Unlike the first embodiment shown in FIG. 1, in this embodiment these materials may be different. The GaAs channel 22 of the n-MOSFET N may be covered with a gallium oxide (GaO) dielectric layer 25 that is be thermally grown or deposited to a thickness selected for a desired device performance. However, the Si0.75Ge0.25 material forming the channel layer 23 of the p-MOSFET P is covered by a conventional SiO2 dielectric material 31, which is also thermally grown or deposited to a thickness selected for a desired device performance. Other high-K materials, such as TaO5, Hf02 or any other gate dielectric material may also be used for p-MOSFET P.

Once the dielectric layers 25 and 31 have been formed, the gate electrode layers 26 are then deposited (STEP 6) and may be of polysilicon or any other suitable metal with a desired work function. The electrode material may be the same for both the n- and p-MOSFET devices N and P. The p and n doping in the top channel layers 22 and 23 and the gate work function, i.e. the gate material, will define the threshold voltage of the device.

Once the gate electrode layers 26 have been formed, the source-drain extensions may be implanted and are preferably arsenic (As) for the n-MOSFET N and boron (B) for the p-MOSFET P. As in the first embodiment, nitride spacer layers 27 are then deposited around the gate regions (STEP 7). The nitride spacer layers 27 are preferably between 25 nm and 100 nm thick. Finally, the source-drain metal contact layers 28 of any suitable metal are then deposited (STEP 8).

1. A semiconductor device having a substrate on which are formed a first field effect transistor, comprising:
a first source-drain region;
a first channel of a first, n-type conductivity semiconductor material formed on the substrate;
a first gate region;
a first dielectric region that separates the first channel from the first gate region;
a second field effect transistor, comprising:
a second source-drain region;
a second channel of a second, p-type conductivity semiconductor material dissimilar to the first material and formed on the substrate;
a second gate region, and
a second dielectric region that separates the first channel from the first gate region.

2. The device as claimed in claim 1, wherein the substrate on which the first and second channels of the respective first and second field effect transistors are formed comprises a silicon substrate.

3. The device as claimed in claim 1, wherein the first, n-type conductivity semiconductor material used for the first channel comprises silicon and the second p-type conductivity semiconductor material used for the second channel comprises a Si—Ge alloy.

4. The device as claimed in claim 2, wherein the first, n-type conductivity semiconductor material used for the first channel comprises a different material to that of the substrate.

5. The device as claimed in claim 2, the first, n-type conductivity semiconductor material used for the first channel comprises GaAs and the second p-type conductivity semiconductor material used for the second channel comprises a Si—Ge alloy.

6. The device as claimed in claim 1, wherein the substrate comprises a layer of GaP over a base Si layer.

7. The device as claimed in claim 6, wherein at least one intermediate layer in the form of a superlattice stack is provided between the base Si layer and the first, n-type conductivity semiconductor material forming the first channel to absorb lattice mismatching.

8. The device as claimed in claim 7, wherein each intermediate layer is composed of two thin alternating layers that are each between 5 nm and 10 nm thick in a superlattice stack of between four and six layers inclusive.

9. The device as claimed in claim 7, wherein a first intermediate layer lies over the GaP layer above the Si base layer and comprises alternating layers of GaP and GaAsP, and a second intermediate layer lies over the first intermediate layer and comprises alternating layers of GaAsP and GaAs.

10. The device as claimed in claim 1, wherein said the first dielectric region is formed from a different material to that of the second dielectric region.

11. The device as claimed in claim 1, wherein the first dielectric region comprises a GaO dielectric layer.

12. A semiconductor device having a substrate comprising a layer of GaP over a base Si layer on which GaP layer are formed a first field effect transistor, comprising:
a first source-drain region;
a first channel of a first, n-type conductivity semiconductor material formed on said substrate;
a first gate region;
a first dielectric region that separates the first channel from the first gate region;
a second field effect transistor, comprising:
a second source-drain region;
a second channel of a second, p-type conductivity semiconductor material formed on the substrate;
a second gate region; and
a second dielectric region that separates the first channel from the first gate region.

13. The device as claimed in claim 12, wherein the first, n-type conductivity semiconductor material used for the first channel comprises GaAs and the second p-type conductivity semiconductor material used for the second channel comprises a Si—Ge alloy.

14. The device as claimed in claim 13, wherein at least one intermediate layer in the form of a superlattice stack is provided between the base Si layer and the GaAs first channel to absorb lattice mismatching.

15. The device as claimed in claim 14, wherein each intermediate layer is composed of two thin alternating layers that may each be between 5 nm and 10 nm thick in a superlattice stack of between four and six layers.

16. The device as claimed in claim 14, wherein a first intermediate layer laid down over the GaP layer above the Si base layer comprises alternating layers of GaP and GaAsP and a second intermediate layer laid down over the first intermediate layer comprises alternating layers of GaAsP and GaAs.

17. The-A device as claimed in claim 14, wherein the at least one intermediate layer comprises a Ge layer on a Si substrate.

18. The device as claimed in claim 14, wherein the first dielectric region is formed from a different material to that of the second dielectric region.

19. The device as claimed in claim 14, wherein the first dielectric region comprises a GaO dielectric layer.

20. A method of manufacturing a semiconductor device having a substrate on which are formed first and second field effect transistors, the first field effect transistor having a first channel of a first, n-type conductivity semiconductor material formed on the substrate and the second field effect transistor comprises a second channel of a second, p-type conductivity semiconductor material dissimilar to the first material and formed on the substrate, the method comprising:
depositing a first layer of a first-type semiconductor material on the substrate to form the first channel;
removing the first layer at a region where a second-type field effect transistor is to be formed;
depositing a second layer of a second-type semiconductor material dissimilar to the first material on said substrate in said region where the first material was removed;
forming an isolation region between the first and the second materials;
depositing first and second gate dielectric layers over the first and second materials respectively;
depositing gate electrode layers over the first and the second gate dielectric layers; and
forming source-drain contact layers at each of the two gate regions over the first and the second materials.

21. The method as claimed in claim 20, wherein the first-type semiconductor material comprises silicon and the second-type conductivity semiconductor material comprises a Si—Ge alloy.

22. The method as claimed in claim 20, wherein the substrate comprises a layer of GaP over a base Si layer and the first-type semiconductor material comprises a second Si layer, the deposition of the GaP layer and the second Si layer being accomplished by epitaxial growth in a single epitaxy growth step.

23. A method of manufacturing a semiconductor device having a substrate on which are formed first and second field effect transistors, the first field effect transistor having a first channel of a first, n-type conductivity semiconductor material formed on the substrate and the second field effect transistor having a second channel of a second, p-type conductivity semiconductor material dissimilar to the first material and formed on the substrate, the method comprising:
depositing on a Si substrate a GaP layer and at least one superlattice stack intermediate layer;
depositing a first layer of a first-type semiconductor material on the intermediate layer;
removing said first layer at a region where a second-type field effect transistor is to be formed;
depositing a second layer of a second-type semiconductor material dissimilar to the first material on the substrate in the region where the first material was removed;
forming an isolation region between the first and the second materials;
depositing first and second gate dielectric layers over the first and second materials respectively;
depositing gate electrode layers over the first and the second gate dielectric layers; and
forming source-drain contact layers at each of the two gate regions over the first and the second materials.

24. The method as claimed in claim 23, wherein the deposition of the GaP layer, the at least one superlattice stack intermediate layer and the first layer of the first-type semiconductor material is accomplished by epitaxial growth in a single epitaxy growth step.

25. The method as claimed in claim 23, wherein the first-type semiconductor material comprises GaAs and the second-type conductivity semiconductor material comprises a Si—Ge alloy.

26. The method as claimed in claim 23, wherein each the intermediate layer is composed of two thin alternating layers that are each between 5 nm and 10 nm thick in a superlattice stack of between four and six layers inclusive.

27. The method as claimed in claim 23, wherein two superlattice stack intermediate layers are deposited over the GaP layer, of which a first intermediate layer is deposited over the Si substrate and comprises alternating layers of GaP and GaAsP and of which a second intermediate layer is deposited over said first intermediate layer and comprises alternating layers of GaAsP and GaAs.

28. The method as claimed in claim 23, wherein the first gate dielectric layer is formed from a different material to that of the second date dielectric layer.

29. The method device as claimed in claim 23, wherein the first date dielectric layer comprises a GaO dielectric layer.
